(19) United States
(12) Patent Application Publication
(10) Pub. No.: US 2011/0149531 A1
(43) Pub. Date: Jun. 23, 2011

(54) ELECTRONIC APPARATUS

(76) Inventor: Takahiro Sugai, Kokubunji-shi (JP)

(21) Appl. No.: 12/960,255

(22) Filed: Dec. 3, 2010

(30) Foreign Application Priority Data
Dec. 17, 2009 (JP) JP 2009-286680

(51) Int. Cl. H05K 7/00

(52) U.S. Cl. 361/748

(57) ABSTRACT

According to one embodiment, an electronic apparatus includes a housing having electric insulation properties, a substrate installed in the housing, a trace provided on an inner surface of the housing, and a connector including a connector body formed of an elastic body and compressed between the inner surface of the housing and the substrate, and a conductor buried in the connector body so as to penetrate the connector body, the connector electrically connecting the trace and a terminal of the substrate by the conductor. The housing includes a holder integrally formed therewith, the holder defining an attachment position of the connector. The holder protrudes from the inner surface of the housing in such a manner as to support the substrate and controls a degree of compression of the connector body.

### CROSS-REFERENCE TO RELATED APPLICATIONS

This application is based upon and claims the benefit of priority from Japanese Patent Application No. 2009-286680, filed Dec. 17, 2009; the entire contents of which are incorporated herein by reference.

### FIELD

Embodiments described herein relate generally to an electronic apparatus in which a circuit board and a trace on the inside of the apparatus housing are electrically connected by an elastic connector.

BACKGROUND

There is an increasing need to make the housing of a portable electronic apparatus, such as a portable computer, thinner.

As a way of doing this, Jpn. Pat. Appln. KOKAI Publication No. 2005-268521, for example, discloses an electronic apparatus in which a conductive adhesive is printed on the inside of the housing to form a circuit pattern, and a circuit element such as a connector is bonded to a land of the pattern.

Since the pattern and element are electrically connected by the conductive adhesive of the pattern, this arrangement saves space and makes the housing thinner.

However, since the element is directly bonded to the inside of the housing, should the housing be deformed by external pressure, the stress produced at the connection of the element and pattern may break or damage the connection.

An example of a conventional means for electrically connecting circuit elements to the circuit pattern is a compressible rubber connector. This connector usually comprises an elastic body of, for example, silicone rubber in which wires are embedded. When elements are fixed to the housing, the connector body is compressed between housing and elements so that the wires penetrate the body.

This brings the opposite ends of the wires into contact with pattern lands and elements, respectively, thereby establishing electrical connections.

Since the degree of compression of the connector body must be precisely controlled to maintain electrical continuity, the body is usually enclosed in a connector holder which restricts compression of the body between the housing and circuit elements. This avoids excessive compression, thus preventing the wires from buckling and ensuring appropriate contact pressures where the wires meet the lands and elements.

However, requiring a connector holder separate from the housing increases the number of components to be assembled and necessitates providing a structure on the housing to support the holder. Thus, the conventional arrangement involving a connector holder can make the housing more complex, increases the number of steps required to manufacture the electronic apparatus, and so increases the manufacturing cost.

### BRIEF DESCRIPTION OF THE DRAWINGS

A general architecture that implements the various feature of the embodiments will now be described with reference to the drawings. The drawings and the associated descriptions are provided to illustrate the embodiments and not to limit the scope of the invention.

FIG. 1 is an exemplary perspective view showing a portable computer according to the first embodiment.

FIG. 2 is an exemplary perspective view of the dismantled housing in which a plurality of traces and a plurality of adhesive filled portions are comprised, and connector having a connection terminal according to the first embodiment.

FIG. 3 is an exemplary cross sectional view of the housing in which the connector is bonded to a connector mounting region by a conductive adhesive according to the first embodiment.

FIG. 4 is an exemplary cross sectional view showing the positional relation between the housing in which the traces and adhesive filled portions are comprised and the connector according to the first embodiment.

FIG. 5 is an exemplary cross sectional view of the housing in which the traces and a printed circuit board are electrically connected by a rubber connector according to the first embodiment.

FIG. 6 is an exemplary cross sectional view of the portable computer shown in FIG. 5, taken along the line F6-F6.

FIG. 7 is an exemplary cross sectional view of the housing in which the rubber connector is not pressured between the printed circuit board and the bottom surface of the housing according to the first embodiment.

FIG. 8 is an exemplary perspective view of the dismantled housing in which a plurality of traces and a plurality of adhesive filled portions are comprised, and the connector having a connection terminal according to the second embodiment.

FIG. 9 is an exemplary cross sectional view of the housing in which the traces and a printed circuit board are electrically connected by a rubber connector according to the second embodiment.

### DETAILED DESCRIPTION

Various embodiments will be described hereinafter with reference to the accompanying drawings.

In general, according to one embodiment, an electronic apparatus includes: a housing having electric insulation properties; a substrate installed in the housing; a trace provided on an inner surface of the housing; and a connector including a connector body formed of an elastic body and compressed between the inner surface of the housing and the substrate, and a conductor buried in the connector body so as to penetrate the connector body, the connector electrically connecting the trace and a terminal of the substrate by the conductor. The housing includes a holder integrally formed therewith, the holder defining an attachment position of the connector. The holder protrudes from the inner surface of the housing in such a manner as to support the substrate and controls a degree of compression of the connector body.

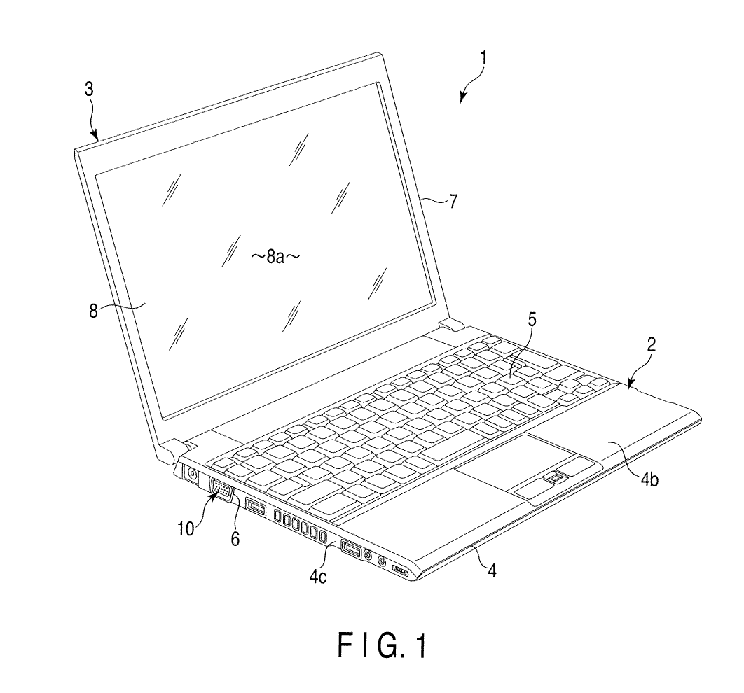

A description will now be given of the first embodiment, with reference to FIGS. 1 to 7.

FIG. 1 is a perspective view showing a portable computer 1 which is an example of an electronic apparatus. The portable computer 1 includes a computer main body 2 and a display module 3.

The computer main body 2 includes a housing 4 which is formed, for example, of synthetic resin and has electric insulation properties. The housing 4 is shaped like a flat box including a bottom wall 4a, an upper wall 4b and sidewall 4c. The upper wall 4b of the housing supports a keyboard 5. The sidewall 4c extends from the side edges of the bottom wall 4a. The sidewall 4c of the housing 4 comprises a rectangular opening 6.

As shown in FIG. 1, the display module 3 includes a display housing 7 and a liquid crystal display panel 8 which is housed in the display housing 7. The display housing 7 is shaped like a flat box and is about the same size as the computer main body 2. The liquid crystal display panel 8 comprises a screen 8a which shows image information and text information. The screen 8a is exposed from the front surface of the display housing 7.

The display module 3 is supported at the rear edge of the computer main body 2 by a hinge not shown in the figures. The display module 3 is pivotable between a closed position where the display module 3 is laid parallel to the computer main body 2 to cover the keyboard 5 and an open position where the display module 3 is raised relative to the computer main body 2 to expose the keyboard 5 and the screen 8a.

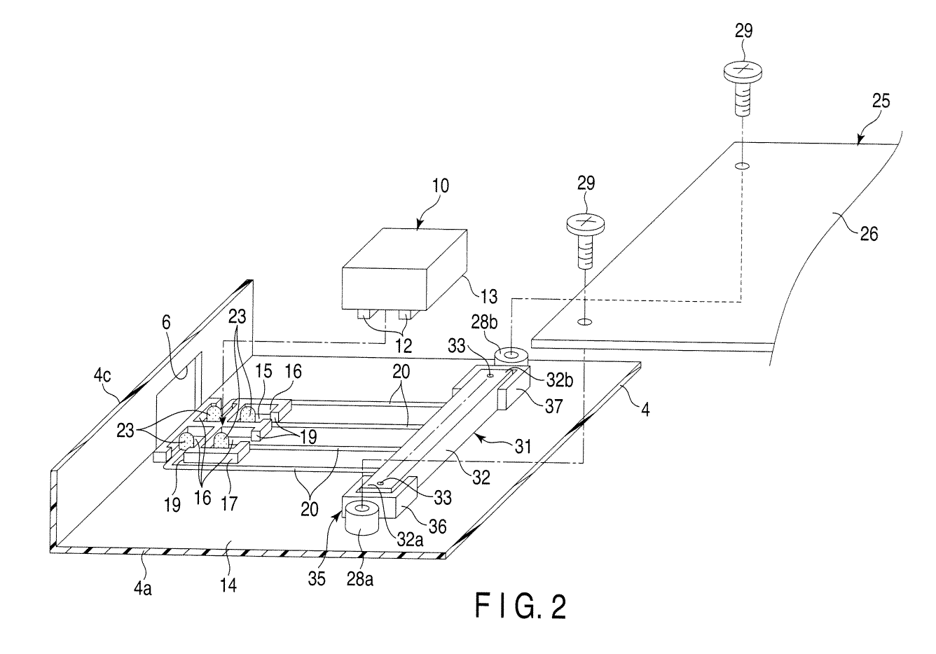

As shown in FIGS. 1 and 2, a connector 10 is arranged in the opening 6 of the sidewall 4c. The connector 10 is used to connect peripheral equipment such as an external monitor (not shown in the figures) to the portable computer 1. The connector 10 comprises a plurality of connection terminals 12. The connection terminals 12 are arranged like a matrix on a flat bottom surface 13 of the connector 10.

The connector 10 is supported on an upper surface 14 of the bottom wall 4a of the housing 4. The upper surface 14 of the bottom wall 4a is an example of the inner surface of the housing. The upper surface 14 of the bottom wall 4a comprises a connector mounting region 15. The connector mounting region 15 is adjacent to the opening 6, and the connector 10 is fixed to the housing 4 in the connector mounting region 15.

As shown in FIG. 2 to FIG. 4, the connector mounting region 15 comprises a plurality of adhesive filled portions 16. The adhesive filled portions 16 are separated to form a lattice by a division wall 17 so as to correspond to the connection terminals 12. The division wall 17 takes the form of a framework which extends upward from the upper surface 14 of the bottom wall 4a, and surrounds each adhesive filled portion 16. Each adhesive filled portion 16 is opened and larger than each connection terminal 12 of the connector 10.

The division wall 17 comprises a plurality of trace introduction portions 19. Each of the trace introduction portions 19 is shaped like a slit opened toward the adhesive filled portion 16. The upper surface 14 of the bottom wall 4a is exposed in the trace introduction portions 19.

As shown in FIG. 2, a plurality of traces 20 are provided on the upper surface 14 of the bottom wall 4a. The traces 20 are formed integrally with the housing 4 by applying the conductive adhesive linearly on the upper surface 14 of the bottom wall 4a. The traces 20 extend widthways parallel to each other and separate from each other. The conductive adhesive is applied on the upper surface 14 of the bottom wall 4a by a screen printing method or a dispensing method, for example.

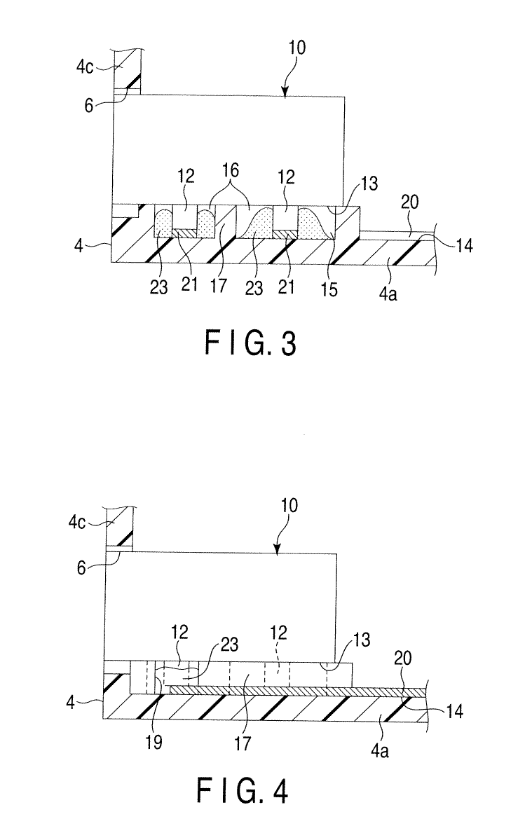

One ends of the traces 20 run through the trace introduction portion 19 of the division wall 17 into the adhesive filled portion 16. As shown in FIG. 3, a land 21 is provided at the end of each traces 20. The lands 21 are placed on the adhesive filled portions 16.

As shown in FIGS. 3 and 4, the connector 10 laid on the division wall 17. The bottom surface 13 of the connector 10 covers the adhesive filled portions 16 from above so that the connection terminals 12 of the connector 10 are inserted into the adhesive filled portions 16 and laid on the lands 21.

A conductive adhesive 23 is filled in each of the adhesive filled portions 16. The conductive adhesive 23 is hardened so as to integrally cover the connection terminals 12 and the lands 21. The conductive adhesive 23 filled in the adjoined adhesive filled portions 16 is kept electrically insulated by the division wall 17.

In this structure, the connector 10 is fixed to the connector mounting region 15 of the housing 4 by the conductive adhesive 23 so that the connection terminals 12 of the connector 10 are kept electrically connected to the lands 21 of the traces 20.

As shown in FIG. 2, the ends of the traces 20 opposed to the lands 21 are placed away from the connector mounting region 15, and arranged side by side and separate from each other on the upper surface 14 of the bottom wall 4a.

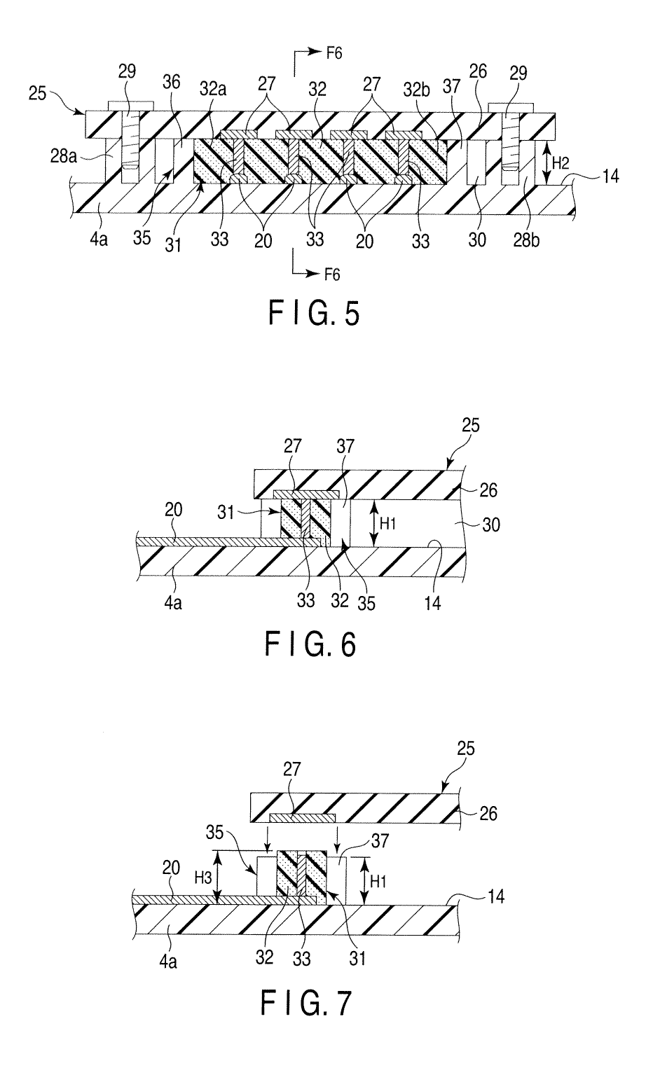

Further, a printed circuit board 25 is housed inside the housing 4. As shown in FIG. 5, the printed circuit board 25 comprises a substrate 26 and a plurality of pads 27 formed on the bottom at one end of the substrate 26. The pads 27 are examples of the terminal which is electrically conducted to the conductor pattern of the printed circuit board 25. The pads 27 are arranged side by side and separate from each other to correspond to the ends of the traces 20 opposed to the lands 21.

One end of the substrate 26 is fixed to a pair of bosses 28a and 28b projecting from the upper surface 14 of the bottom wall 4a by screws 29 which are fixtures. The substrate 26 is placed parallel to the upper surface 14 of the bottom wall 4a, and a gap 30 the same height as the bosses 28a and 28b is formed between the substrate 26 and the upper surface 14 of the bottom wall 4a.

The pads 27 of the substrate 26 face the ends of the traces 20 opposed to the lands 21. The pads 27 and the ends of the traces 20 opposed to the lands 21 are electrically connected through a rubber connector 31. The rubber connector 31 is also called “an elastic connector,” and provided between the bottom wall 4a of the housing 4 and the one end of the substrate 26.

As shown in FIG. 5 to FIG. 7, the rubber connector 31 comprises a connector body 32 and a plurality of wires 33. The connector body 32 is formed of an elastic body of, for example, silicone rubber, and is long and narrow, extending transversely to the traces 20. The connector body 32 comprises a first end portion 32a, a second end portion 32b opposed to the first end portion 32a. The first end portion 32a and the second end portion 32b are separate from each other lengthways relative to the connector body 32.

The wires 33 are an example of the conductor, and oriented vertically and buried in the connector body 32. The wires 33 are arranged that they are parallel to and separate from each other.

The connector body 32 is vertically compressed between the bottom wall 4a of the housing 4 and the substrate 26. This brings the opposite ends of the wires 33 into contact with the traces 20 and the pads 27, respectively, thereby establishing electrical connections between the traces 20 and the pads 27 by the wires 33.

As shown in FIG. 2 and FIG. 5, a holder 35 which defines a position where the rubber connector 31 is attached to the housing 4 is integrally formed on the upper surface 14 of the bottom wall 4a of the housing 4. The holder 35 according to this embodiment comprises a first engaging portion 36 and a second engaging portion 37.

The first engaging portion 36 takes the form of a framework and extends upward from the upper surface 14 of the bottom wall 4a. The first engaging portion 36 surrounds the first end portion 32a of the connector body 32 on three sides to hold the first end portion 32a. In the same way, the second engaging portion 37 takes the form of a framework and extends upward from the upper surface 14 of the bottom wall 4a. The second engaging portion 37 surrounds the second end portion 32b of the connector body 32 on three sides to hold the first end portion 32b. The first engaging portion 36 and the second engaging portion 37 are lengthways separate from each other.

The connector body 32 is held by the holder 35 between the first engaging portion 36 and the second engaging portion 37. With this structure, the position of the connector body 32 is determined relative to the width and length of the housing 4.

The first engaging portion 36 and the second engaging portion 37 are placed between the pair of bosses 28a and 28b through which the substrate 26 is fixed. The height Hl of the first engaging portion 36 and the second engaging portion 37 is the same as the height H2 of the bosses 28a and 28b. The upper surfaces of the first engaging portion 36 and the second engaging portion 37 are brought into contact with the lower surface of the substrate 26 which are fixed to the bosses 28a and 28b to support the substrate 26.

As shown in FIG. 7, the height H1 of the first engaging portion 36 and the second engaging portion 37 is set to be smaller than the thickness H3 of the connector body 32 before the connector body 32 is compressed. With this structure, as shown in FIG. 2, the upper portion of the connector body 32 protrudes from the first engaging portion 36 and the second engaging portion 37 before the substrate 26 is fixed to the bosses 28a and 28b.

A description will now be given of a procedure for connecting the traces 20 printed on the bottom wall 4a of the housing 4 and the pads 27 of the printed circuit board 25 by way of the rubber connector 31.

First, the first end portion 32a of the connector body 32 is engaged in the first engaging portion 36 of the holder 35, and the second end portion 32b of the connector body 32 is engaged in the second engaging portion 37. This decides the position of the rubber connector 31 relative to the bottom wall 4a of the housing 4. In this state, the upper portion of the connector body 32 protrudes from the first engaging portion 36 and the second engaging portion 37, as shown in FIGS. 2 and 7.

Next, the printed circuit board 25 is fixed to the upper surfaces of the bosses 28a and 28b, which projecting from the bottom wall 4a, by the screws 29. The substrate 26 of the printed circuit board 25 is brought into contact with the upper portion of the connector body 32, and at the same time, the connector body 32 is pressed toward the bottom wall 4a of the housing 4.

As a result, the connector body 32 is vertically compressed between the bottom wall 4a and the substrate 26. The lower surface of the substrate 26 is brought into contact with the upper surfaces of the first engaging portion 36 and the second engaging portion 37, and the substrate 26 is supported by the first engaging portion 36 and the second engaging portion 37 from the bottom.

In this structure, the distance between the substrate 26 and the bottom wall 4a is determined, the degree of compression of the connector body 32 is controlled. In other words, the first engaging portion 36 and the second engaging portion 37 of the holder 35 define the position of the connector body 32 relative to the bottom wall 4a of the housing 4, and at the same time, avoid excessive compression of the connector body 32.

When the connector body 32 is compressed between the substrate 26 and the bottom wall 4a, one ends of the wires 33 are brought into contact with the traces 20 with a suitable pressure, and the other ends the wires 33 are brought into contact with the pads 27 of the printed circuit board 25 with a suitable pressure. With this structure, the traces 20 of the housing 4 and the printed circuit board 25 are kept electrically connected by the rubber connector 31.

According to the aforementioned first embodiment, the holder 35 which defines the position of the connector body 32 relative to the bottom wall 4a of the housing 4 is formed integrally with the housing 4, the holder 35 projecting from the upper surface 14 of the bottom wall 4a. In addition, the height H1 of the first engaging portion 36 and the second engaging portion 37 of the holder 35 is smaller than the thickness H3 of the connector body 32 before being compressed.

With this structure, when the substrate 26 of the printed circuit board 25 is fixed to the bosses 28a and 28b, the upper surfaces of the first engaging portion 36 and the second engaging portion 37 are brought into contact with the lower surface of the substrate 26, and excessive compression of the connector body 32 is avoided.

That is, the height H1 of the first engaging portion 36 and the second engaging portion 37 of the holder 35 is designed to suitably adjust the degree of compression of the connector body 32. This prevents the wires 33 buried in the connector body 32 from buckling, and ensures suitable contact pressures between the wires 33 and the traces 20 and between the wires 33 and the pads 27. This structure enhances the stability of electrical connection between the traces 20 and the printed circuit board 25.

According to the first embodiment, the holder 35 which controls the degree of compression of the connector body 32 is formed integrally with the bottom wall 4a of the housing 4. This eliminates the need to employ a connector holder dedicated to control the degree of compression of the rubber connector 31, thereby decreasing the number of components to be assembled to the portable computer 1.

In addition, this structure eliminates the need to employ an element to support the connector holder on the bottom wall 4a of the housing 4. Thus, the structure of the housing 4 can be simplified, and the number of steps required to manufacture the portable computer 1 can be decreased.

As can be seen from the above, the present embodiment realizes the advantages of decreasing the manufacturing cost of the portable computer 1 and providing the portable computer 1 at low cost.

The present invention is not limited to the first embodiment, but may be modified without departing from the spirit or scope of the general inventive concept.

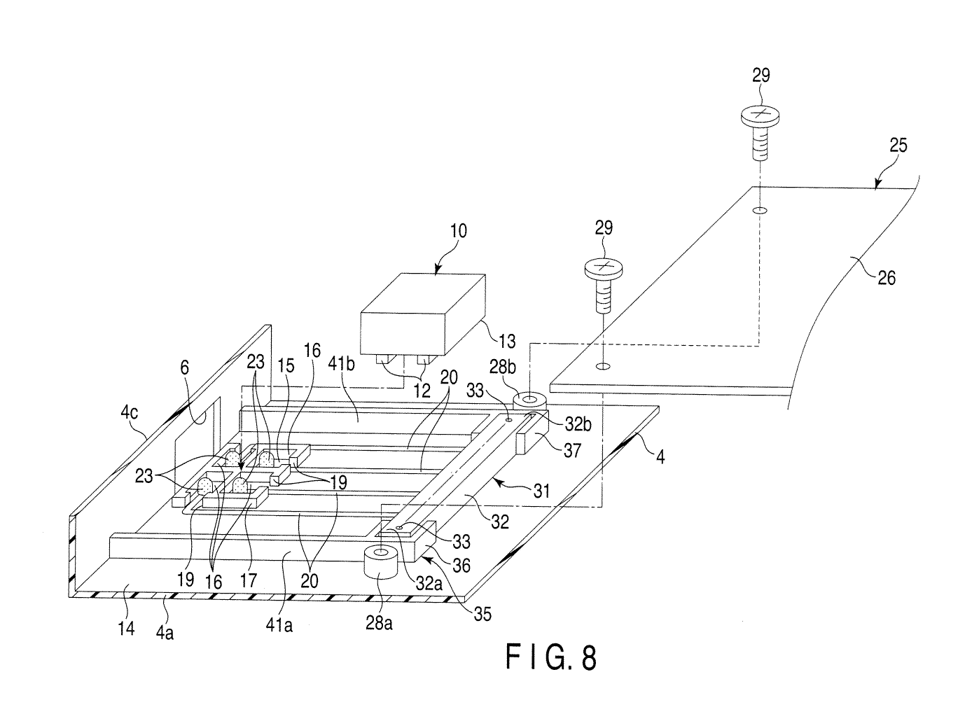

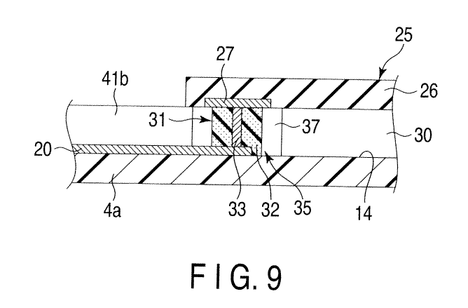

For example, FIGS. 8 and 9 show the second embodiment. The structures of a portable computer 1 of the second embodiment are similar to the structures described in the first embodiment except that a bottom wall 4a of a housing 4 in which traces 20 are provided is reinforced. The following descriptions will therefore focus mainly on how the second embodiment differs from the first embodiment. The structural components or elements that are similar to those of the first embodiment will be denoted by the same reference symbols, and a repetitive description of such components or elements will be omitted.

As shown in FIG. 8, a pair of extensions 41a and 41b are formed integrally with an upper surface 14 of the bottom wall 4a of the housing 4. The extensions 41a and 41b are raised relative to the bottom wall 4a and arranged along or parallel to the traces 20. In this embodiment traces 20 are provided between the extensions 41a and 41b.

The extensions 41a and 41b are arranged separate from each other and parallel to each other. The extensions 41a and 41b connects a first engaging portion 36 of a holder 35 to a sidewall 4c of the housing 4, and a second engaging portion 37 of a holder 35 to a sidewall 4c, respectively. The first engaging portion 36 and the second engaging portion 37 of the holder 35 are formed integrally with the extensions 41a and 41b, respectively, and they are raised relative to the bottom wall 4a of the housing 4.

In this structure, the traces 20 are provided between the extensions 41a and 41b. The extensions 41a and 41b functions as a rib to reinforce the region of the bottom wall 4a in which the traces 20 are provided. This improves stiffness of the bottom wall 4a and prevents the bottom wall 4a from bending, thereby preventing the traces 20 provided on the bottom wall 4a by a conductive adhesive from being broken or damaged.

The extensions may be provided between the neighboring traces. In such a case, the extensions and the traces are alternately arranged on the bottom wall, and this further improves stiffness of the bottom wall and protects each trace by the extensions.

In the first embodiment, the housing is formed of synthetic resin, but may be formed of metal such as magnesium and aluminum. When the housing is formed of metal, the traces are isolated from the housing by forming the traces on an insulating layer on the inner surface of the housing, for example.

In addition, the holder is not limited to the structure of surrounding the first and second end portions of the connector body, but may be the structure of enclosing the whole connection body, for example.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic apparatus comprising:
a housing having electric insulation properties;
a substrate installed in the housing;
a trace provided on an inner surface of the housing; and
a connector comprising a connector body formed of an elastic body and compressed between the inner surface of the housing and the substrate, and a conductor buried in the connector body so as to penetrate the connector body, the connector electrically connecting the trace and a terminal of the substrate by means of the conductor,
wherein the housing comprises a holder integrally formed therewith, the holder defining an attachment position of the connector,
the holder protrudes from the inner surface of the housing in such a manner as to support the substrate and controls a degree of compression of the connector body.

2. The electronic apparatus of claim 1, wherein
a height of the holder is smaller than a thickness of the connector body before the connector body is compressed.

3. The electronic apparatus of claim 2, wherein
the connector body comprises a first end portion and a second end portion opposed to the first end portion, and
the holder comprises a first engaging portion configured to hold the first end portion of the connector body and a second engaging portion configured to hold the second end portion of the connector body.

4. The electronic apparatus of claim 3, wherein each of the first and second engaging portions takes a form of framework and protrudes from the inner surface of the housing.

5. The electronic apparatus of claim 4 further comprising a plurality of bosses projecting from the inner surface of the housing toward the substrate, the bosses having a height same as a height of the holder,
wherein the substrate is fixed to upper surfaces of the bosses by fixtures.

6. The electronic apparatus of claim 5, wherein
the holder configured to hold the connector is placed between the plurality of bosses.

7. An electronic apparatus comprising:
a housing having electric insulation properties;
a substrate installed in the housing;
a trace provided on an inner surface of the housing; and
a connector comprising a connector body formed of an elastic body and compressed between the inner surface of the housing and the substrate, and a conductor buried in the connector body so as to penetrate the connector body, the connector electrically connecting the trace and a terminal of the substrate by means of the conductor,
wherein the housing comprises a holder integrally formed therewith, the holder defining an attachment position of the connector, and
the holder protrudes from the inner surface of the housing in such a manner as to support the substrate and controls a degree of compression of the connector body, and
an extension extending along the trace is integrally formed on the inner surface of the housing.

8. The electronic apparatus of claim 7, wherein
the trace is formed integrally with the housing by printing a conductive adhesive on the inner surface of the housing.

9. The electronic apparatus of claim 8, wherein
the extension and the holder are integrally formed with each other.
